(19) United States
(12) Patent Application Publication
(10) Pub. No.: US 2006/0220658 A1
(43) Pub. Date: Oct. 5, 2006

(54) Sensor system for moisture and salt measurement using microstripline

(76) Inventor: Seichi Okamura, Hamamatsu-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/392,660

(22) Filed: Mar. 30, 2006

Related U.S. Application Data
(60) Provisional application No. 60/666,569, filed on Mar. 31, 2005.

(51) Int. Cl. G01R 27/04

(52) U.S. Cl. 324/640

(57) ABSTRACT

A method for measuring moisture content and salt concentration contained in soil is provided. It is based on an idea of using a ratio of microwave signals propagating through a microstripline. Using the microwaves at 2 GHz and 10 GHz, the measurement is carried out on a sample of sand. Although the measurement result has non-negligible error, it confirms that the sensor has an ability of measuring the moisture content and salt concentration.

### CROSS-REFERENCE TO RELATED APPLICATIONS

This application claims the benefit of U.S. Provisional Application No. 60/666,569, filed Mar. 31, 2005.

### BACKGROUND OF THE INVENTION

1. Field of the Invention

The present invention relates to a sensor system for moisture content and salt concentration contained in soil, and a method for measuring the same.

2. Description of the Related Art

The measurement of the moisture content and the salt concentration contained in the soil is very important for farming. It is necessary especially for controlling of irrigation to grow much plant with preventing the salt graining at a surface of ground in a dried region. However, there is few sensors having ability of measuring the moisture and the concentration, and development of a new sensor is desired. If such a sensor is popular in the world, a farmland in the dried region helped by the irrigation will be prevented from salt damage and that will contribute to increase of food production.

### BRIEF SUMMARY OF THE INVENTION

According to an aspect of the present invention, there is provided a sensor system for measuring moisture content and salt concentration in soil, which comprises: a microstripline board having a microstripline over which a sample is put, an analyzer, connected to the microstripline board, for applying microwave to an input side of the microstripline to provide measured data of the sample from an output side of the microstripline, and a processor, connected to the analyzer, for storing and processing the measured data.

According to another aspect of the present invention, there is provided a method for measuring the moisture content and the salt concentration in the soil, which comprises: preparing a microstripline board having a microstripline, putting a sample over the microstripline, applying microwave to the microstripline to provide sample data, and processing the sample data to provide the moisture content and salt concentration contained in the sample.

### BRIEF DESCRIPTION OF THE SEVERAL VIEWS OF THE DRAWINGS

FIG. 1 is a perspective view showing a structure of a microstripline according to the invention.

FIGS. 2A and 2B are charts showing difference between measured values in the salt concentrations in both a real part and an imaginary part.

FIG. 3 is a chart showing influence to attenuation due to change of pressure.

FIG. 4 is a chart showing the influence to phase shift due to the change of the pressure.

FIG. 5 is a chart showing a ratio of the attenuation and the phase shift.

FIG. 6 is a chart showing the ratio at 2 GHz.

FIG. 7 is a chart showing the ratio at 10 GHz.

FIG. 8 is a chart showing predicted moisture content.

FIG. 9 is a chart showing predicted salt concentration measured at 2 GHz.

### DETAILED DESCRIPTION OF THE INVENTION

A popular sensor that measures the moisture content of a material containing much water is using microwaves. In this invention a transmission method is provided to realize the sensor for the moisture content and the salt concentration measurement of the soil.

In the transmission method the sensor using a microstripline is provided for the measurement because it has good result in the measurement of the moisture content of high moist material. A principle of the measurement of the sensor is using a ratio of the attenuation to the phase shift of the microwave transmitted through the microstripline surrounded by the soil.

The principle of the invention will be first described.

The sensor used in the invention is made by the microstripline that detects information about the material under test put on a line. The microwave which come into the line propagates through the line being affected by the material on the line. The output microwave from the line has the information about the material as changes of the amplitude or phase of the wave. The two changes are measured as the attenuation or the phase shift. In the measurement system of the sensor the two changes are combined to one signal. The signal is the ratio of the attenuation to the phase shift.

Both of the attenuation and the phase shift are affected by moisture content M, salt concentration S, density of material p, and the effective sensor length 1. The attenuation and the phase shift denoted by AA and ΔΦ, respectively, are expressed in Eq.1 and Eq.2.
ΔA=R_{A}(ρ).g_{A}(M)·C_{A}(S)·l (1)
ΔΦ=R_{Φ(ρ).}gφ(M)·C_{Φ}(S)·l (2)

where R_{A}(ρ) and R_{φ}(ρ) are the functions for the attenuation and the phase shift on the density, g_{A}(M) and g_{Φ}(M) are the functions for the attenuation and the phase shift on the moisture content, C_{A}(S) and C_{Φ}(S) are the functions for the attenuation and the phase shift on the salt concentration, respectively.

The ratio of Eq.1 to Eq.2 is shown in Eq.3.

$$\begin{matrix}\frac{Δ A}{Δ Φ} = \frac{{R}_{A} ( ρ ) \cdot {g}_{A} ( M ) \cdot {C}_{A} ( S ) \cdot 1}{{R}_{Φ} ( ρ ) \cdot {g}_{Φ} ( M ) \cdot {C}_{Φ} ( S ) \cdot 1} = k ( ρ ) \cdot φ ( M ) \cdot η ( S ) & ( 3 ) \\ k ( ρ ) = {R}_{A} ( ρ ) / {R}_{Φ} ( ρ ) & ( 4 ) \\ φ ( M ) = {g}_{A} ( M ) / {g}_{Φ} ( M ) & ( 5 ) \\ η ( S ) = {C}_{A} ( S ) / {C}_{Φ} ( S ) & ( 6 )\end{matrix}$$

where k(ρ), Φ(M), and η(S) are the functions of the ratio on the density, the moisture content, and the salt concentration, respectively.

The ratio expressed in Eq.3 has no variable for the effective sensor length of l. Then the detected signals from the sensor is not affected by the length of material or roughness at the surface of the material. Also, it has less dependence to the change of density of material. The fact that the ratio is useful for the measurement of moisture content has been confirmed experimentally. It is reconfirmed in this invention.

The aim of this research is to know the possibility of measuring the moisture content and the salt concentration of soil, but sand is tested instead of soil because of the easiness in handling. The moisture content M of sand on wet basis is defined as following.

$$M = \frac{{W}_{w}}{{W}_{d} + {W}_{w}} \times 100 \% \qquad ( 7 )$$

where W_{w} and W_{d} are the masses of water and dry material, respectively. The mass of perfect dried sand, i.e. 0% sand, is measured after drying more than 8 hours at temperature of 80 degree in Celsius.

The moisture content and salt concentration of the sand are adjusted by adding tap water and salt. The moisture contents are 0, 5, 10, 15, and 20%, and the salt concentrations are 0, 1, 2, and 3%.

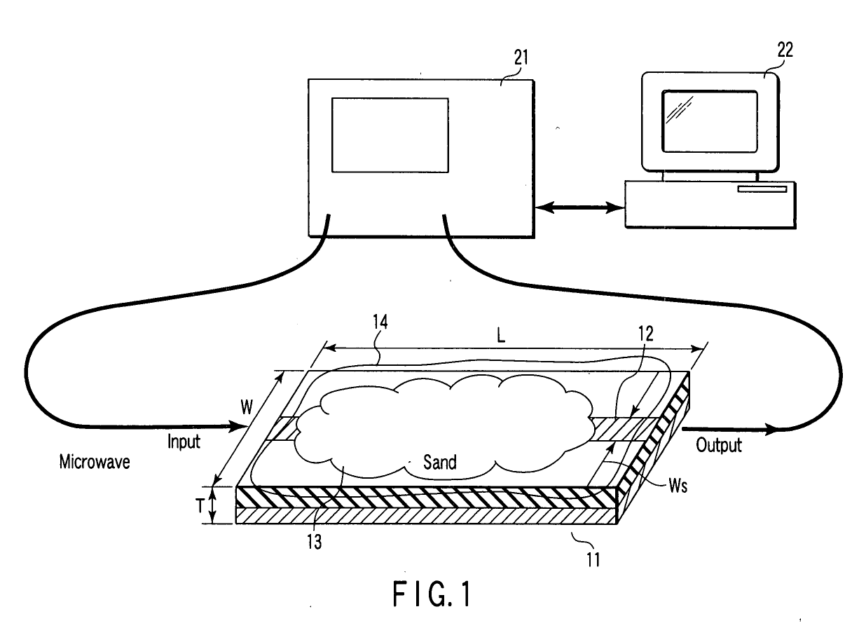

The setup of the sensor is constructed with a board 11 of microstripline, a network analyzer 21 (Anritsu 37347C), and a processor 22 such as personal computers as shown in FIG. 1. The microstripline board 11 is made of a copper double side epoxy glass board and has a length L of 150 mm, a width W of 100 mm, and a thickness T of 1.6 mm, respectively. An upper conductive layer 12 of copper has a width Ws of 2.7 mm. Microwave generated at the analyzer 21 propagates through the microstripline 11 and detected by the analyzer 21. As one example of the soil, sand 13 under test is put on the microstripline 11, and the moisture and the salt contained in the sand 13 are measured. The strip of the line is covered with a polyethylene film 14 and protected from the damage caused by the sand pressing on it. The measured data from the analyzer 21 are processed and stored by the processor 22.

The sample of the soil is put on the microstripline board. However the microstripline board may be embedded in the soil to measure the moisture content and the salt concentration.

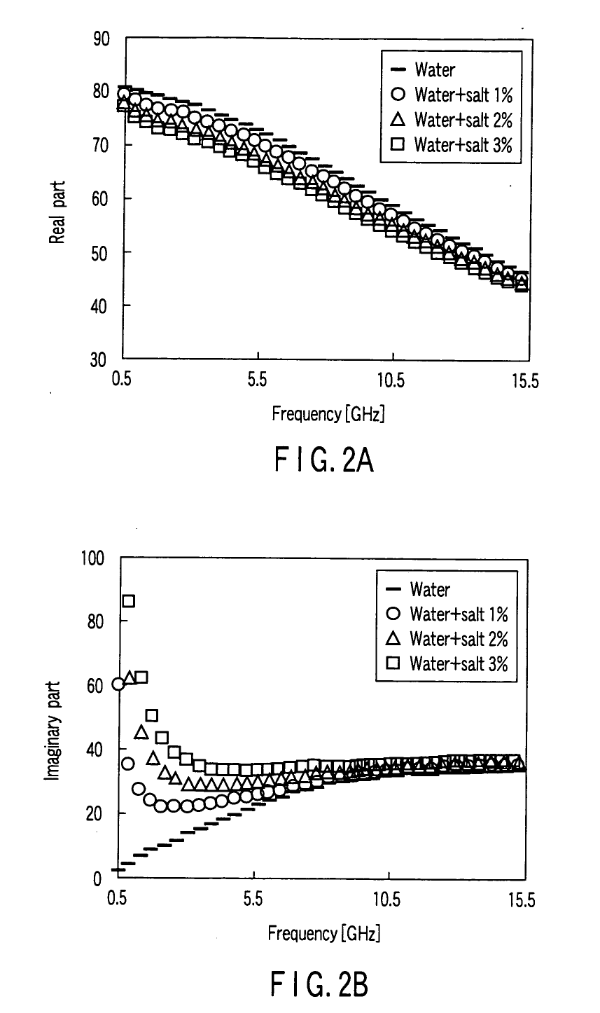

Measurement frequency is determined from the frequency characteristics of the sand, the water, and the salt water. The permittivity of the dried sand is about 3 and has little dependence in the measured frequency. The permittivity of each of the water and the salt water is measured by a dielectric probe of a network analyzer (HP85070) and the result is shown in FIGS. 2A, 2B. Measured samples are tap water and the weight concentration of salt is 1, 2, and 3%.

It is seen from the FIGS. 2A, 2B that there is difference between the measured values in the salt concentrations in both the real part and imaginary part. However, the difference becomes smaller in increasing of the measuring frequency and that is conspicuous in the imaginary part. The attenuation of microwave comes mainly from the imaginary part of the permittivity. From these results, the frequency used in the measurement is decided to 2 GHz and 10 GHz.

The experiment on the sensor and the ratio of the attenuation to the phase shift will be provided.

Considering the difference in the nature of soil, the sand under the test is pressed by some weights to change the density of the sand. To prevent the effects due to the difference of the size and of the density of the sample sand, the method using the ratio of the attenuation to the phase shift of microwave is adopted.

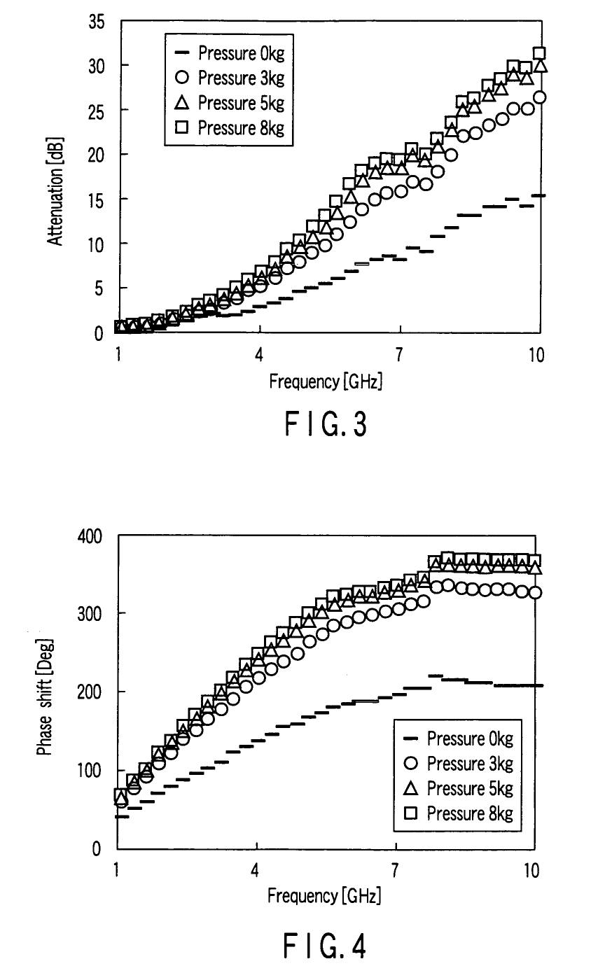

The sample sand contains tap water of 10% on the weight. The density of the sand is changed by pressing the top of the sand by putting some weights. The maximum weight is 8 kg and the pressed area of the sand is about 7×15 cm², then the maximum pressure is about 0.08 kg/cm². The influence due to the change of the pressure is seen in the attenuation in FIG. 3 and the phase shift in FIG. 4. These results express that both the attenuation and phase shift are changed easily by the difference in the nature of the soil.

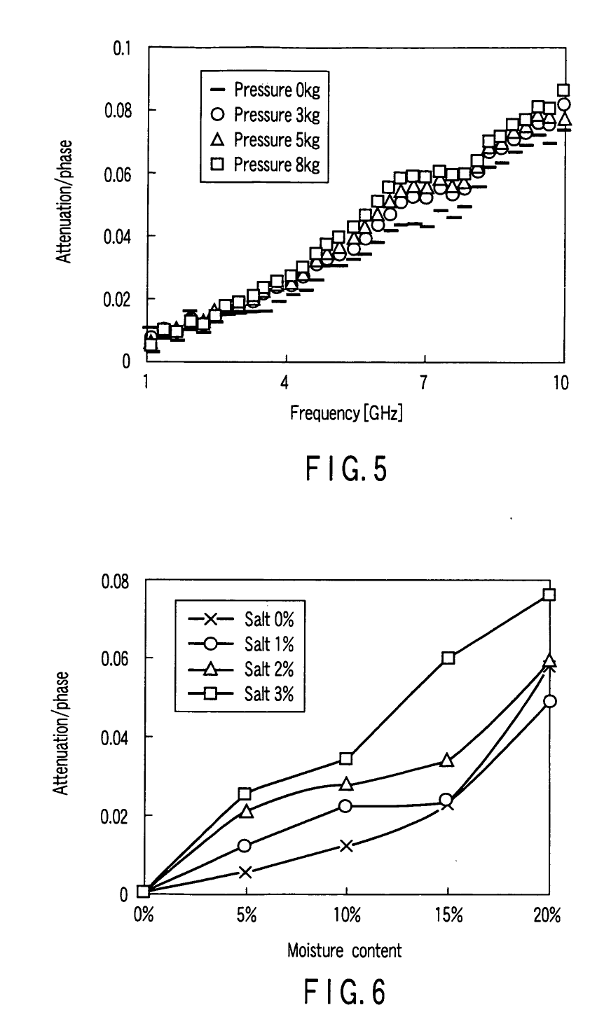

On the other hand, the influence due to the change of the pressure is decreased by using the ratio of the attenuation to the phase shift shown in FIG. 5. It is decreased by one fifth at 10 GHz than that of the attenuation or the phase shift itself. Hence, the ratio method is used in this embodiment to measure the moisture content and the salt concentration.

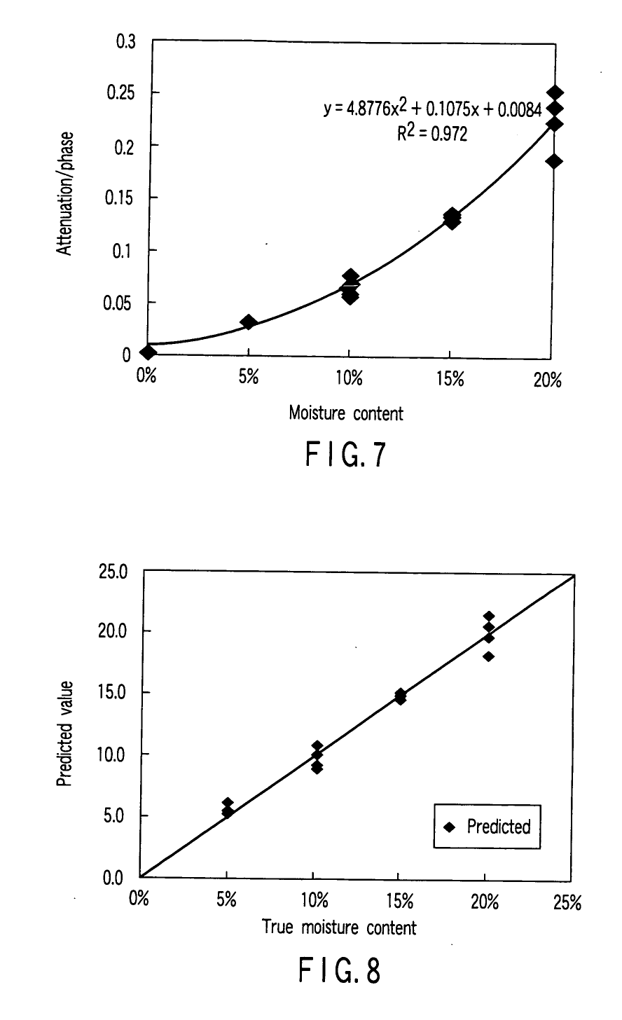

The moisture content and the salt concentration containing in the sample sand are measured by using the ratio method. The moisture content of the sample is made to 5, 10, 15, and 20%. The salt concentration on each sample is 0, 1, 2, and 3%. The ratio of the attenuation to the phase shift at 2 GHz is shown in FIG. 6, and that at 10 GHz is shown in FIG. 7.

The ratio at 2 GHz in FIG. 6 changes by both the moisture content and the salt concentration. Contrarily, the difference of the ratio due to the change of the salt concentration is small at 10 GHz in FIG. 7. The ratio is considered to be mainly changed only by the moisture content of the sample sand at 10 GHz.

As shown in FIG. 7, the moisture content of the sand can be measured by using the microwave at 10 GHz in spite of whether salt is existing in the sand or not. Therefore, the moisture content or the salt concentration of the sample of the sand under the measurement can be measured by next procedure.

An equation shown by y= . . . in FIG. 7 is an equation showing calibrated values which are experimentally obtained from measured data.

In the equation, R² is a statistically obtained value that shows how much the measured data deviates from the value indicated by the solid line expressed by the equation. If this value is 1, all of the points are on the solid line.

1. To know the moisture content of a sample, measure the ratio explained above by using the microwave at 10 GHz.

2. From the measured ratio at 10 GHz, the moisture content of the sand is predicted using a chart or a table. In this embodiment FIG. 7 can be used as the chart.

3. To know the salt concentration of the sample, measure the ratio by using the microwave at 2 GHz.

4. From the measured ratio at 2 GHz and the predicted moisture content, the salt concentration of the sand is predicted using a chart or a table. FIG. 6 can be used as the chart.

5. The moisture content and the salt concentration are the predicted values as the step 2 and 4, respectively.

To check the above procedure, the samples used in the measurement in FIG. 6 and FIG. 7 are measured and the moisture content and the salt concentration of the samples are predicted.

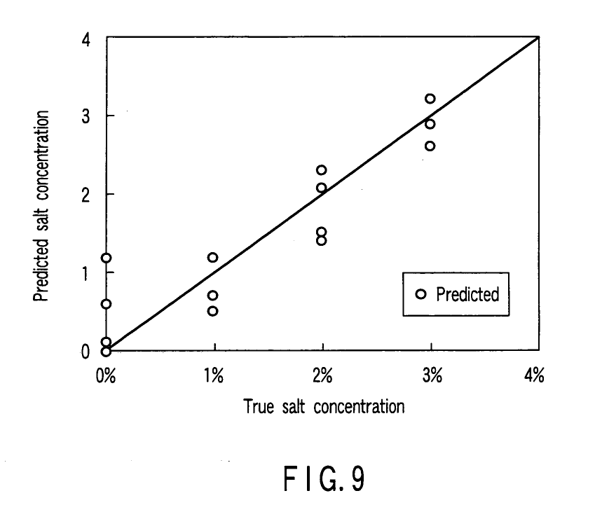

The results are shown in FIG. 8 and FIG. 9. The straight line in each Figure corresponds to the ideal relation. The predicted results on moisture content have small error but the predicted results on salt concentration have not small error. However, the possibility of simultaneous measurement of the moisture content and the salt concentration can be confirmed.

A new idea of a sensor for measuring the moisture content and the salt concentration has been presented. One of the features in the sensor is made of the microstripline operating at 2 and 10 GHz, on which a sample under test is put for the measurement. Another is the adoption of the ratio of the attenuation to the phase shift on the microwaves traveling through the line. Although the measurement result of the embodiment on the sand has non-negligible error, it confirms that the new sensor has an ability of measuring the moisture content and the salt concentration. In next step of the research on the sensor more research will be needed to reduce the measurement error.

What is claimed is:

1. A sensor system for measuring moisture content and salt concentration in soil comprising:
a microstripline board having a microstripline over which a sample is put;
an analyzer, connected to the microstripline board, for applying microwave to an input side of the microstripline to provide measured data of the sample from an output side of the microstripline; and
a processor, connected to the analyzer, for storing and processing measured data.

2. The sensor system according to claim 1, wherein the measured data is the ratio of attenuation to phase shift of the microwave.

3. The sensor system according to claim 2, wherein the attenuation and the phase shift of the microwave are given by changes of amplitude and phase of the microwave, respectively.

4. The sensor system according to claim 1, wherein the sample is soil.

5. The sensor system according to claim 3, wherein the two changes are combined to one signal.

6. The sensor system according to claim 1, wherein frequency range of the microwave is 1-10 GHz, preferably 2 and 10 GHz.

7. The sensor system according to claim 1, wherein at least the microstripline is covered with a protection film.

8. The sensor system according to claim 7, wherein the protection film is comprised of a polyethylene film.

9. A method for measuring moisture content and salt concentration contained in soil comprising:
preparing a microstripline board having a microstripline;
putting a sample over the microstripline;
applying microwave to the microstripline to provide sample data; and
processing the sample data to provide the moisture content and salt concentration contained in the sample.

10. The method according to claim 9, wherein output from the microstripline is applied to an analyzer to provide the sample data.

11. The method according to claim 10, wherein the analyzer is connected to a processor to process the sample data.

12. The method according to claim 9, wherein the sample data is the ratio of attenuation to phase shift of the microwave.

13. The method according to claim 9, wherein at least the microstripline is covered with a protection film.

14. The method according to claim 12, wherein the attenuation and the phase shift of the microwave are given by changes of amplitude and phase of the microwave, respectively.

15. The method according to claim 14, wherein the two changes are combined to one signal.
